(19) United States
(12) Patent Application Publication
(10) Pub. No.: US 2012/0188701 A1
(43) Pub. Date: Jul. 26, 2012

(54) DOCKING STATION AND ELECTRONIC APPARATUS USING THE SAME

(75) Inventors: Hsin Lu, Taipei City (TW); Yung-Hsiang Chen, Taipei City (TW); Cheng-Min Huang, Taipei City (TW); Hsiang-Ling Liu, Taipei City (TW); Cheng-Jui Lin, Taipei City (TW); Hsin Yeh, Taipei City (TW)

(73) Assignee: COMPAL ELECTRONICS, INC., Taipei City (TW)

(21) Appl. No.: 13/351,199

(22) Filed: Jan. 16, 2012

Related U.S. Application Data
(60) Provisional application No. 61/435,787, filed on Jan. 25, 2011.

(51) Int. Cl. H05K 7/00; G06F 1/16

(52) U.S. Cl. 361/679.26; 361/679.01

(57) ABSTRACT

A docking station, an electronic apparatus and a portable device are provided. The electronic apparatus comprises a portable device having a display surface and a docking station having a base and a connecting module. The base has a supporting surface. The portable device is adapted to be attached to the supporting surface. The connecting module has a first pivot and a second pivot. The first pivot is connected and pivoted to the base, and the second pivot is detachably pivoted to the portable device, such that the portable device is adapted to rotate relatively to the docking station.

### CROSS-REFERENCE TO RELATED APPLICATION

This application claims the priority benefits of U.S. provisional application Ser. No. 61/435,787, filed on Jan. 25, 2011. The entirety of the above-mentioned patent applications is hereby incorporated by reference herein and made a part of this specification.

### BACKGROUND OF THE INVENTION

1. Field of the Invention

The present invention generally relates to an electronic apparatus. More particularly, the present invention relates to a docking station, a portable device and an electronic apparatus using the same.

2. Description of Related Art

Along with the development of technology, portable devices, such as tablet personal computers (tablet PC) and electronic readers (E-Reader), are now in widespread use. In general, control information is input to a conventional tablet personal computer through a touch screen. However, operation convenience of the touch screen does not satisfy all of the user's demands, so that a related docking station is developed accordingly. However, the operation process of the docking station is complicated and the price is high. Therefore, it is an important issue of the computer industry to provide a docking station with a good attachment and improve operation convenience of the docking station and the portable device.

### SUMMARY OF THE INVENTION

The present invention provides an electronic apparatus comprising a portable device and a docking station. The portable device having a display surface. The docking station having a base and a connecting module, and the base having a supporting surface. The connecting module having a first pivot and a second pivot, wherein the first pivot is connected and pivoted to the base, and the second pivot is detachably pivoted to the portable device, such that the portable device is adapted to rotate relatively to the docking station.

The present invention further provides a docking station adapted to be detachably connected to a connecting module. The docking station comprises a base and a connecting module. The base has a supporting surface. The connecting module having a pivot, wherein the pivot is connected and pivoted to the base and the connecting module is adapted to rotate relatively to the docking station.

The present invention further provides a portable device with a display surface, adapted to be detachably connected to a connecting module. The portable device comprises a main body and a fasten member. The fasten member is disposed on the main body and is used to detachably connect to the connecting module by a pivot, wherein the portable device is fastened on the connecting module when the pivot is restricted by the fastening member.

According to an embodiment of the present invention, the first pivot is pivoted to the base along a first and the second pivot is detachably pivoted to the portable device along a second axis, wherein the second axis is parallel to the first axis.

According to an embodiment of the present invention, the portable device is adapted to be separated from the base when the second pivot is detached from the portable device.

According to an embodiment of the present invention, when the supporting surface faces the display surface when the portable device is attached to the base.

According to an embodiment of the present invention, the portable device has a back surface opposing to the display surface, the second pivot is detachably pivoted to the back surface, the back surface leans against the connecting module when the portable device is attached to the base, and the connecting module expands from the back surface when the portable device stands on the supporting surface.

According to an embodiment of the present invention, when the back surface leans against the connecting module, the portable device is adapted to be expanded from or attached to the supporting surface by the relative pivoting between the connecting module and the base.

According to an embodiment of the present invention, the portable device comprises a main body and a fastening member, wherein the fastening member, disposed on the main body and is used to detachably connect to the second pivot, wherein the portable device is fastened on the connecting module when the second pivot is restricted by the fastening member.

According to an embodiment of the present invention, the fastening member is a locking member and the locking member is adapted to slide between a locking position and a releasing position, wherein the second pivot is restricted on the main body by the locking member when the locking member is in the locking position, and the second pivot is adapted to be detached from the main body when the locking member is in the releasing position.

According to an embodiment of the present invention, the first pivot is a shaft or a hinge and the second pivot is a shaft or a hinge.

According to an embodiment of the present invention, the docking station further comprises an input interface disposed on the base, wherein the input interface is a keyboard module, a touch keyboard, or a touch panel.

In light of the above, in the present invention, through the connecting module disposed on the docking station and detachably disposed on the portable device, the portable device suitable for rotating relatively to the docking station and standing thereon is provided. Therefore, the operation convenience of the docking station and the portable device is improved and the flexibility in using the portable device is also enhanced.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates an electronic apparatus in an appearance of a portable device detached to a docking station according to an embodiment of the present invention.

FIG. 2 is the electronic apparatus in FIG. 1 illustrating the portable device attached and standing on the docking station.

FIG. 3 is the electronic apparatus in FIG. 1 illustrating the portable device leaning against the connecting module.

FIGS. 4 to 6 are the electronic apparatus in FIG. 1 illustrating three different statuses of the portable device rotating relatively to the base.

FIG. 7 is a partial enlarged view of section A in FIG. 6 showing the connecting module is locked to the locking member.

FIG. 8 is a schematic view of the locking member in the releasing position relative to the connecting module.

FIG. 9 is a schematic view of the locking member in the locking position relative to the connecting module.

### DESCRIPTION OF THE EMBODIMENTS

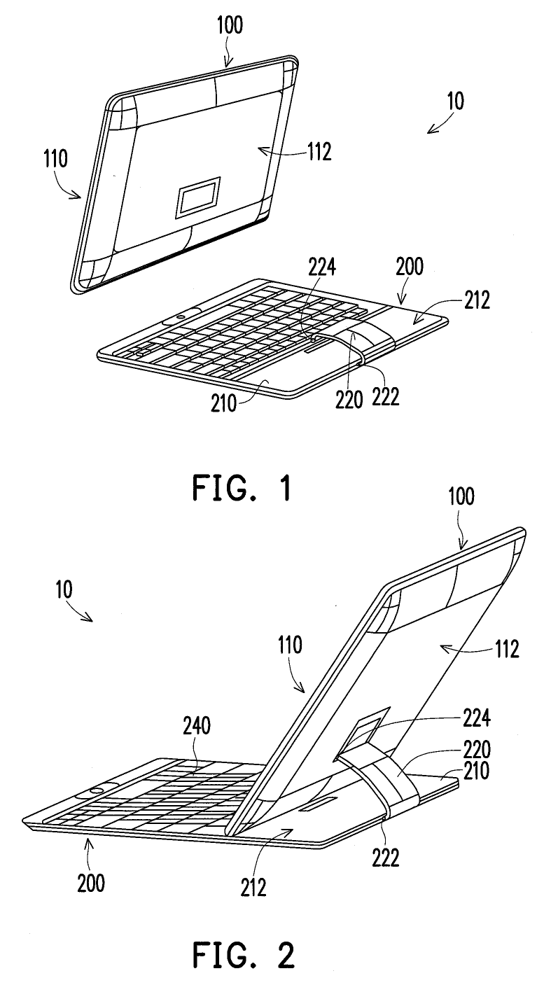

FIG. 1 illustrates an electronic apparatus in an appearance of a portable device detached to a docking station according to an embodiment of the present invention. FIG. 2 is the electronic apparatus in FIG. 1 illustrating the portable device attached and standing on the docking station. Referring to FIG. 1 and FIG. 2, according to an embodiment of the present invention, the electronic apparatus 10 includes a portable device 100, a docking station 200 and a connecting module 220. The portable device 100 has a display surface 110, wherein the portable device 100 can be a tablet personal computer (tablet PC), an electronic reader or any other portable electronic device having a display screen. In the present embodiment, the portable device 100 is a tablet PC.

The docking station 200 is adapted to be detachably connected to a portable device 100 for providing the portable device 100 some peripheral devices such as mouse, printer, external hard drive, network interface adapter (NIC), scanner, etc, so the users of the portable device 100 can enjoy better functionality and expandability. The docking station 200 includes a base 210. According to different product designs, a connecting module can be a part of the docking station or can be divided from the docking station. The base 210 includes a supporting surface 212 and the portable device 100 is adapted to be attached to the supporting surface 212. When the portable device 100 is attached to the base 210, the supporting surface 212 faces the display surface 110. In the present embodiment, the docking station 200 further includes an input interface 240 and the input interface 240 is a keyboard module, a touch keyboard, or a touch panel as shown in FIG. 2. A connecting module 220 has a first pivot 222 and a second pivot 224. According to different product designs, the first pivot 222 of the connecting module 220 is a shat or a hinge and the second pivot 224 of the connecting module 220 is a shaft or a hinge. In this embodiment, the first pivot 222 and the second pivot 224 are the shafts and the present invention is not limited thereto. The first pivot 222 is connected and pivoted to the base 210 along a first axis A1, so the connecting module 220 is adapted to rotate relatively to the base 210 along the first axis A1. The second pivot 224 is detachably pivoted to the portable device 100 along a second axis A2 parallel to the first axis A1, such that the portable device 100 is adapted to rotate relatively to the base 210 and stands on the supporting surface 212, wherein the portable device 100 standing on the supporting surface 212 is supported by the connecting module 220. The portable device 100 can be separated from the base 210 by detaching the second pivot 224 from the portable device 100.

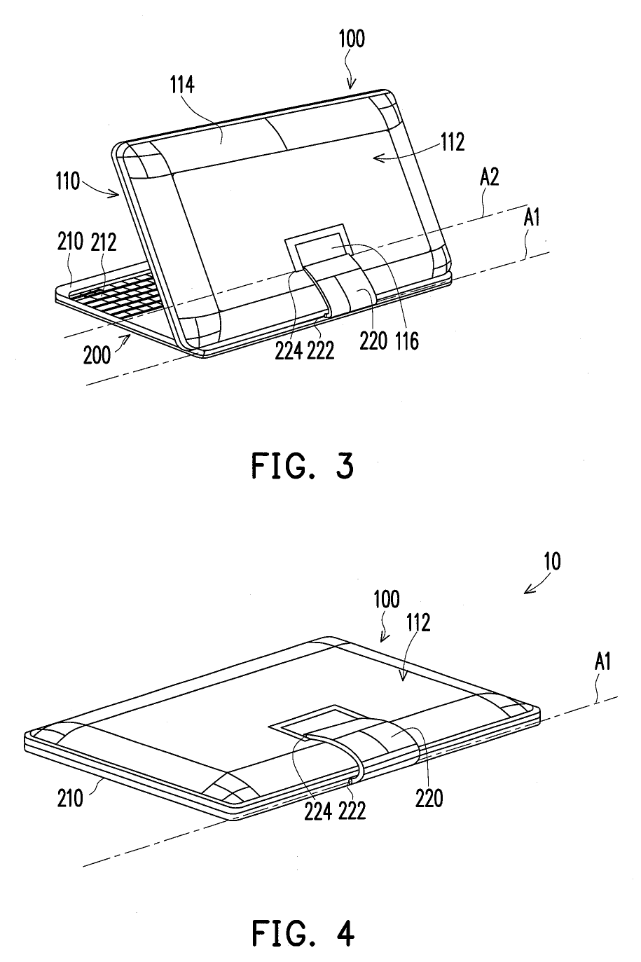

FIG. 3 is the electronic apparatus in FIG. 1 illustrating the portable device leaning against the connecting module. Referring to FIG. 2 and FIG. 3, in detail, the portable device 100 includes a back surface 112 opposite to the display surface 110. The second end 224 is detachably pivoted to the back surface 112, so the portable device 100 is adapted to rotate along the second axis A2. The portable device 100 is adapted to stand on the supporting surface 212 by rotating along the second axis A2 till the connecting module 220 is expanded from the back surface 112 as shown in FIG. 2, so the portable device 100 is supported by the connecting module 220 when standing on the supporting surface 212. When the portable device 100 rotates along the second axis A2 till the back surface 112 leans against the connecting module 220, as shown in FIG. 3, the portable device 100 is adapted to push the connecting module 220 to rotate through the first pivot 222, so the portable device 100 can rotate along the first axis A1, in other words, the portable device 100 is adapted to rotate relatively to the base 210, wherein the portable device 100 is expanded from or attached to the supporting surface 212 by the relative pivoting between the connecting module 220 and the base 210.

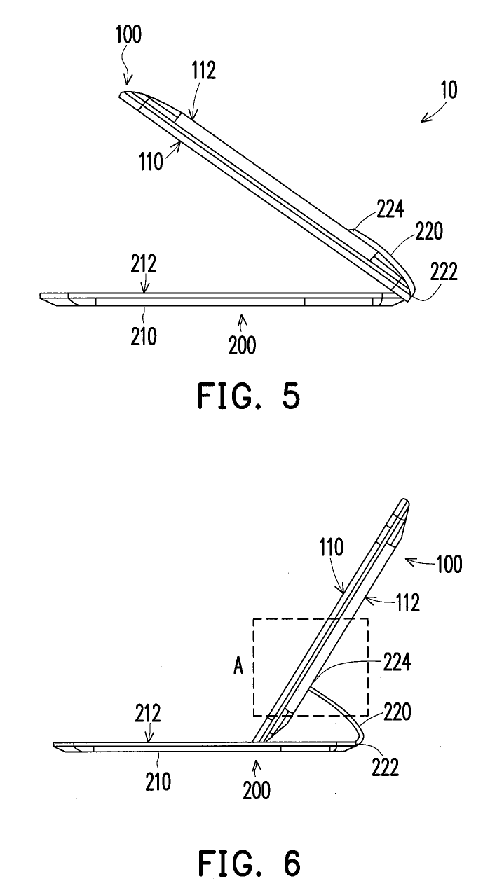

FIGS. 4 to 6 are the electronic apparatus in FIG. 1 illustrating three different statuses of the portable device rotating relatively to the base. When the display surface 110 attaches to the supporting surface 212, as shown in FIG. 4, the connecting module 220 is adapted to be pivoted to the portable device 100, so the portable device 100 leans against the connecting module 220 and is suitable for rotating along the first axis A1, as shown in FIG. 5. When the portable device 100 rotates relatively to the base 210 to a certain angle, as shown in FIG. 6, the portable device 100 can be expanded from the connecting module such that the portable device 100 is adapted to rotate along the second axis A2 and stand on the supporting surface 212 by the support of the connecting module.

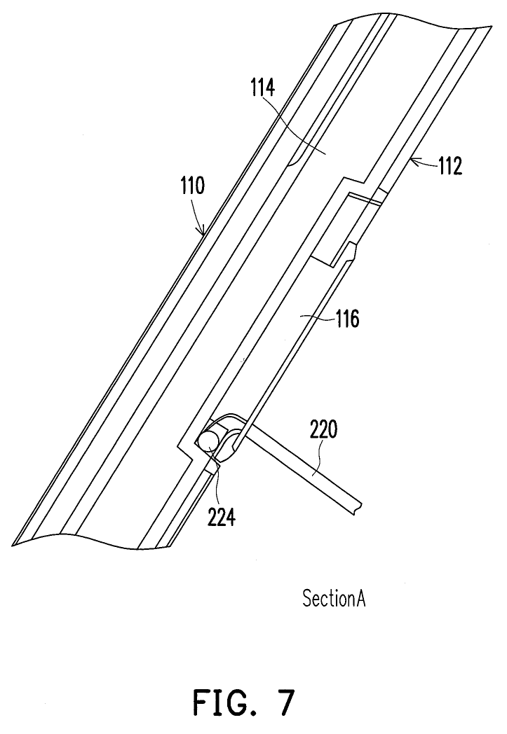

FIG. 7 is a partial enlarged view of section A in FIG. 6 showing the connecting module is fastened to the fastening member. Referring to FIGS. 6 and 7, in detail, the portable device 100 comprises a main body 114 and a fastening member. The fastening member is disposed on the main body and is used to detachably connect to the second pivot, wherein the portable device is fastened on the connecting module when the second pivot is restricted by the fastened member. In the present embodiment, the fastening member is a locking member and the present invention is not limited thereto. When the fastening member is a locking member 116, the locking member 116 is slidably disposed on the main body 114. The locking member 116 is adapted to slide toward the connecting module 220 and lock the second pivot 224 to restrict the portable device 100 onto the connecting module 220.

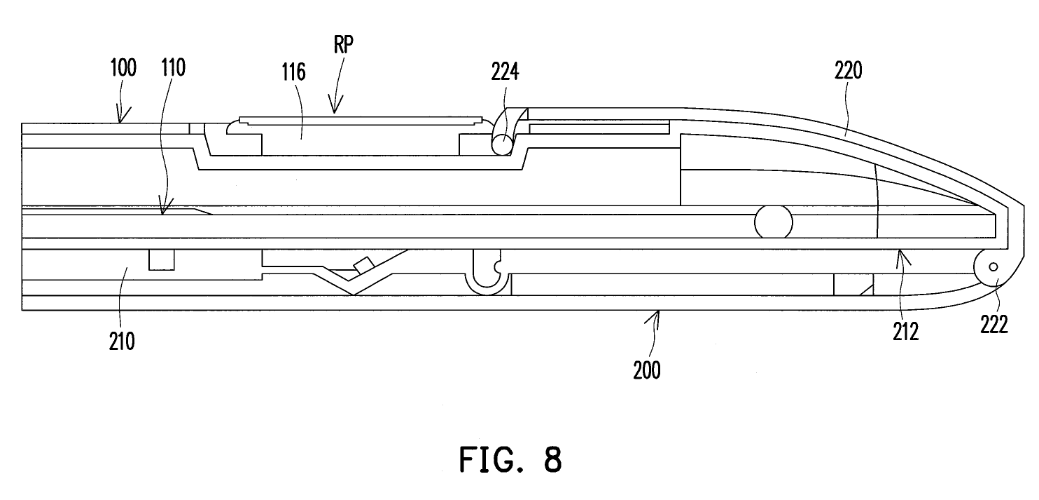

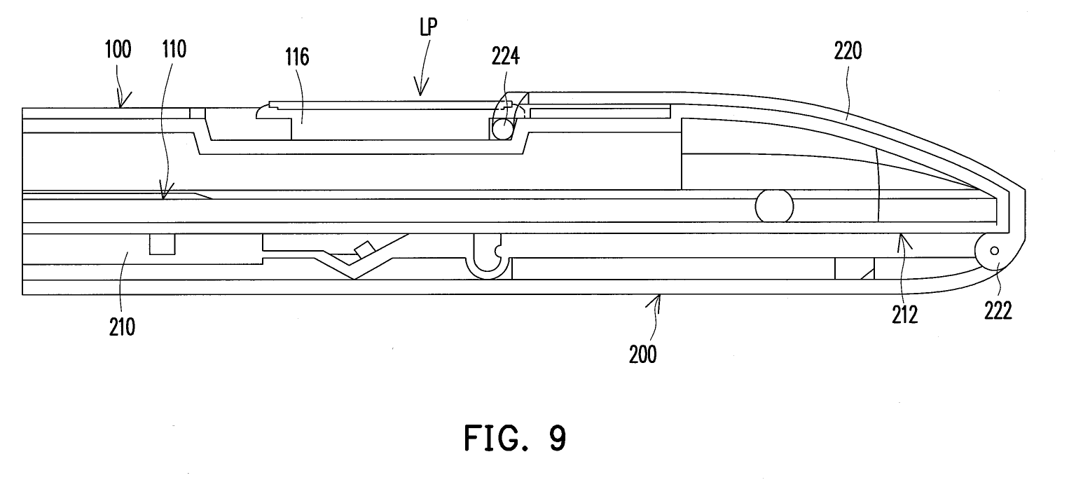

FIG. 8 is a schematic view of the locking member in the releasing position relative to the connecting module. FIG. 9 is a schematic view of the locking member in the locking position relative to the connecting module. Referring to FIGS. 8 and 9, to be more specific, the locking member 116 is adapted to slide between a releasing position RP and a locking position LP. When the locking member 116 slides toward the second pivot 224 to the locking position LP, the locking member 116 is engaged with the second pivot 224 to restrict the connecting module 220 on the portable device 100. When the locking member 116 slides away from the second pivot 224 to the releasing position RP, the second pivot 224 is separated from the locking member 116, so the portable device 100 is adapted to be detached from the connecting module 220.

In light of the foregoing, through the connecting module disposed on the base of the docking station of the present invention, the portable device suitable for rotating relatively to the docking station and standing thereon is provided. In addition, through the locking member slidably disposed on the main body of the portable device, so the portable device can be locked with the connecting module when the locking member slides to the locking position, and can be detached from the connecting module when the locking member slides to the releasing position. Therefore, the operation convenience of the docking station and the portable device is improved and the flexibility in using the portable device is also enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic apparatus, comprising:
a portable device having a display surface;
a docking station having a base and the base having a supporting surface; and
a connecting module having a first pivot and a second pivot, wherein the first pivot is connected and pivoted to the base, and the second pivot is detachably pivoted to the portable device, such that the portable device is adapted to rotate relatively to the docking station.

2. The electronic apparatus as claimed in claim 1, wherein the first pivot is pivoted to the base along a first and the second pivot is detachably pivoted to the portable device along a second axis, wherein the second axis is parallel to the first axis.

3. The electronic apparatus as claimed in claim 1, wherein the portable device being adapted to stand on the supporting surface is supported by the connecting module.

4. The electronic apparatus as claimed in claim 1, wherein the portable device is adapted to be separated from the base when the second pivot is detached from the portable device.

5. The electronic apparatus as claimed in claim 1, wherein the supporting surface faces the display surface when the portable device is attached to the base.

6. The electronic apparatus as claimed in claim 1, wherein the portable device has a back surface opposing to the display surface, the second pivot is detachably pivoted to the back surface, the back surface leans against the connecting module when the portable device is attached to the base, and the connecting module expands from the back surface when the portable device stands on the supporting surface.

7. The electronic apparatus as claimed in claim 6, wherein when the back surface leans against the connecting module, the portable device is adapted to be expanded from or attached to the supporting surface by the relative pivoting between the connecting module and the base.

8. The electronic apparatus as claimed in claim 1, wherein the portable device comprises:
a main body; and
a fastening member, disposed on the main body and is used to detachably connect to the second pivot, wherein the portable device is fastened on the connecting module when the second pivot is restricted by the fastening member.

9. The electronic apparatus as claimed in claim 8, wherein the fastening member is a locking member and the locking member is adapted to slide between a locking position and a releasing position, wherein the second pivot is restricted on the main body by the locking member when the locking member is in the locking position, and the second pivot is adapted to be detached from the main body when the locking member is in the releasing position.

10. The electronic apparatus as claimed in claim 1, wherein the first pivot is a shaft or a hinge and the second pivot is a shaft or a hinge.

11. A docking station, adapted to be detachably connected to a connecting module, comprising:
a base having a supporting surface; and
a connecting module having a pivot, wherein the pivot is connected and pivoted to the base and the connecting module is adapted to rotate relatively to the docking station.

12. The docking station as claimed in claim 11, wherein a portable device having a display surface being adapted to stand on the supporting surface is supported by the connecting module.

13. The docking station as claimed in claim 12, wherein the supporting surface faces the display surface when the portable device is attached to the base.

14. The docking station as claimed in claim 11, wherein the pivot is a shaft or a hinge.

15. The docking station as claimed in claim 11, wherein the docking station further comprises an input interface disposed on the base, wherein the input interface is a keyboard module, a touch keyboard, or a touch panel.

16. A portable device with a display surface, adapted to be detachably connected to a connecting module, comprising:
a main body; and
a fastening member, disposed on the main body and is used to detachably connect to the connecting module by a connecting pivot, wherein the portable device is fastened on the connecting module when the connecting pivot is restricted by the fastening member.

17. The portable device as claimed in claim 16, wherein the portable device being adapted to stand on a supporting surface of a docking station is supported by the connecting module.

18. The portable device as claimed in claim 16, wherein the portable device is adapted to be separated from the connecting module when the connecting pivot is detached from the portable device.

19. The portable device as claimed in claim 16, wherein the fastening member is a locking member and the locking member is adapted to slide between a locking position and a releasing position, wherein the connecting pivot is restricted on the main body by the locking member when the locking member is in the locking position, and the connecting pivot is adapted to be detached from the main body when the locking member is in the releasing position.

20. The portable device as claimed in claim 16, wherein the connecting pivot is a shaft or a hinge.
